(19) United States
(12) Patent Application Publication
(10) Pub. No.: US 2018/0287056 A1
(43) Pub. Date: Oct. 4, 2018

(54) SYNAPSE AND SYNAPSE ARRAY

(71) Applicant: SK hynix Inc., Icheon (KR)

(72) Inventor: Sang-Heon LEE, Icheon (KR)

(21) Appl. No.: 15/799,649

(22) Filed: Oct. 31, 2017

(30) Foreign Application Priority Data
Apr. 4, 2017 (KR) 10-2017-0043558

(51) Int. Cl. H01L 45/00; G06N 3/04; G06N 3/08; G06N 3/063; G11C 11/54; G11C 11/413; H01L 27/24; G11C 13/00

(52) U.S. Cl. CPC H01L 45/1206; G06N 3/049; G06N 3/08; G06N 3/0635; G11C 2213/79; G11C 11/413; H01L 27/2472; G11C 13/003; G11C 11/54

(57) ABSTRACT

A synapse of a neuromorphic device is provided. The synapse of the neuromorphic device may include a variable resistive device, a first transistor, and a second transistor. A drain electrode of the first transistor and a gate electrode of the second transistor may be electrically connected in common with a first electrode of the variable resistive device.

### CROSS-REFERENCE TO RELATED APPLICATIONS

This U.S. non-provisional patent application claims priority under 35 U.S.C. § 119(a) to Korean Patent Application No. 10-2017-0043558, filed on Apr. 4, 2017 in the Korean Intellectual Property Office (KIPO), the disclosure of which is incorporated herein by reference in its entirety.

### BACKGROUND

### 1. Field

The present disclosure relates to synapses and synapse arrays of neuromorphic devices, and more particularly, to a synapse having two transistors and one variable resistive device, and to a synapse array including the synapse.

### 2. Description of the Related Art

Recently, much attention has been paid to devices in the field of neuromorphic technology, which use chips that mimic the human brain. A neuromorphic device based on the neuromorphic technology includes a plurality of pre-synaptic neurons, a plurality of post-synaptic neurons, and a plurality of synapses. A neuromorphic device outputs pulses or spikes having various levels, amplitude, and/or times, according to a learning state of the neuromorphic device.

A synapse of a neuromorphic device outputs data using a capacitor. Accordingly, a capacitance of the capacitor is very important. To increase the capacitance of the capacitor, an occupied area of the capacitor may be increased. Accordingly, miniaturizing the neuromorphic device is very difficult, manufacturing the neuromorphic device is complicated, and the cost of producing the neuromorphic device is raised.

### SUMMARY

Various embodiments of the present disclosure provide a neuromorphic device including a synapse having a variable resistive device.

Various embodiments of the present disclosure provide a neuromorphic device including a synapse having at least two transistors.

Various embodiments of the present disclosure provide synapse arrays including synapses having variable resistive devices.

Various embodiments of the present disclosure provide synapse arrays including synapses. The synapses of the synapse arrays may each have at least two transistors.

In an embodiment of the present disclosure, a synapse of a neuromorphic device may include a variable resistive device, a first transistor, and a second transistor. A drain electrode of the first transistor and a gate electrode of the second transistor may be electrically connected in common with a first electrode of the variable resistive device.

A gate electrode of the first transistor may be electrically connected with a first row line.

A second electrode of the variable resistive electrode may be electrically connected with a second row line.

The first row line and the second row line may extend in parallel with each other in a row direction.

A source electrode of the first transistor may be electrically connected with a first column line.

A source electrode of the second transistor may be electrically connected with a second column line.

The first column line and the second column line may extend in parallel with each other in a column direction.

A drain electrode of the second transistor may be electrically connected with a reference voltage line.

The synapse may further include a load resistor coupled between the drain electrode of the first transistor and the first electrode of the variable resistive device.

The load resistor may have various fixed resistance values.

The variable resistive device may include one of a resistive random access memory (ReRAM) element, a phase-changeable random access memory (PCRAM) element, a magneto-resistive random access memory (MRAM) element, and a conductive bridging random access memory (CBRAM) element.

A resistance state of the variable resistive device may be decreased when a programming voltage is applied to a gate electrode of the first transistor, a first potentiation voltage may be applied to a source electrode of the first transistor, and a second potentiation voltage may be applied to a second electrode of the variable resistive device, the second potentiation voltage being less than the first potentiation voltage.

A resistance state of the variable resistive device may be increased when a programming voltage is applied to a gate electrode of the first transistor, a first depression voltage may be applied to a second electrode of the variable resistive device, and a second depression voltage may be applied to a source electrode of the first transistor, the second depression voltage being less than the first depression voltage.

The variable resistive device may have a plurality of resistance levels. A gate voltage and a transistor current of the second transistor may be changed according to the plurality of resistance levels of the variable resistive device.

In an embodiment of the present disclosure, a synapse array may include a plurality of row lines extending in a row direction, the plurality of row lines including a plurality of first row lines and a plurality of second row lines, a plurality of column lines extending in a column direction, and a plurality of synapses disposed at intersection regions between the row lines and the column lines. Each of the plurality of first row lines and each of the plurality of second row lines may be electrically connected with one of the plurality of synapses, respectively. Each of the plurality of synapses may include a first transistor including a gate electrode electrically connected with one of the plurality of first row lines, a variable resistive device electrically connected with one of the plurality of second row lines, and a second transistor including a gate electrode electrically connected with one of the plurality of second row lines through the variable resistive device.

A first electrode of the variable resistive device may be electrically connected with a drain electrode of the first transistor, and a second electrode of the variable resistive device may be electrically connected with the corresponding one of the plurality of second row lines.

Each of the plurality of column lines may include a first column line and a second column line being electrically connected with one of the plurality of synapses, respectively.

The first column line of each of the plurality of column lines may be electrically connected with a source electrode of the first transistor of each of the plurality of synapses, respectively.

The second column line of each of the plurality of column lines may be electrically connected with a source electrode of the second transistor of each of the plurality of synapses, respectively.

The plurality of column lines may further include a plurality of reference voltage lines, respectively, each of the plurality of reference voltage lines being electrically connected with a drain electrode of the second transistor of each of the plurality of synapses, respectively.

### BRIEF DESCRIPTION OF THE DRAWINGS

FIG. 1 is a diagram schematically illustrating a synapse array including a plurality of synapses in accordance with an embodiment of the present disclosure.

FIG. 2 is a diagram schematically illustrating a synapse of a neuromorphic device in accordance with an embodiment of the present disclosure.

FIG. 3A is a schematic circuit diagram showing an operation for potentiating a variable resistive device of a synapse in accordance with an embodiment of the present disclosure.

FIG. 3B is a timing diagram showing the operation for potentiating the variable resistive device of FIG. 3A.

FIG. 4A is a schematic circuit diagram showing an operation for depressing a variable resistive device of a synapse in accordance with an embodiment of the present disclosure.

FIG. 4B is a timing diagram showing the operation for depressing the variable resistive device of FIG. 4A.

FIG. 5A is a schematic circuit diagram showing an operation for reading out data of a variable resistive device of a synapse in accordance with the embodiment of the present disclosure.

FIG. 5B is a timing diagram showing the operation for reading out data of the variable resistive device of FIG. 5A.

FIG. 6 is a log-scale graph illustrating a characteristic of an output current depending on a read voltage of a synapse in accordance with an embodiment of the present disclosure.

FIG. 7 is a diagram schematically illustrating a pattern recognition system in accordance with an embodiment of the present disclosure.

### DETAILED DESCRIPTION

Various embodiments will be described below in more detail with reference to the accompanying drawings. Embodiments of the present disclosure may, however, have different forms and should not be construed as limited to the embodiments set forth herein. Rather, these embodiments are provided so that this disclosure will be thorough and complete, and will fully convey the scope of the claims to those skilled in the art.

Throughout the specification, like reference numerals refer to the same elements. Therefore, although the same or similar reference numerals are not mentioned or described in the corresponding drawing, the reference numerals may be described with reference to other drawings. Furthermore, although elements are not represented by reference numerals, the elements may be described with reference to other drawings.

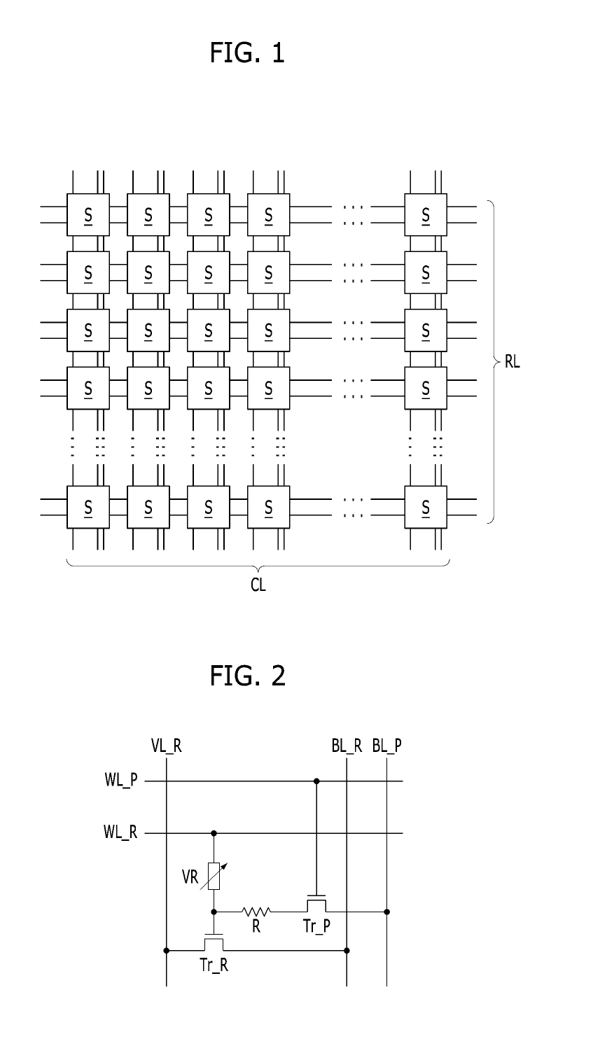

FIG. 1 is a diagram schematically illustrating a synapse array including a plurality of synapses in accordance with an embodiment of the present disclosure.

Referring to FIG. 1, the synapse array may include a plurality of row lines RL extending in a row direction, a plurality of column lines CL extending in a column direction, and a plurality of synapses S disposed at intersection regions between the row lines RL and the column lines CL. The intersection regions may be spaces located where the row lines RL and the column lines CL overlap in a direction crossing the row direction and the column direction.

FIG. 2 is a diagram schematically illustrating a synapse S of a neuromorphic device in accordance with an embodiment of the present disclosure.

Referring to FIG. 2, each of the plurality of row lines RL illustrated in FIG. 1 may include a programming word line WL_P and a reading word line WL_R. Each of the plurality of column lines CL illustrated in FIG. 1 may include a programming bit line BL_P, a reading bit line BL_R, and a reference voltage line VL_R.

The synapse S may be driven when at least one of the row lines WL_P and WL_R and at least one of the column lines BL_P, BL_R, and VL_P are activated at the same time. Specifically, the synapse S coupled between at least one of the activated word lines WL_P and WL_R and at least one of the activated column lines BL_P, BL_R, and VL_R may activated. That is, in a random access memory (RAM) or NOR flash memory, the synapses on the same row line RL or the same column line CL are not activated at the same time.

Referring again to FIG. 2, the synapse S may include a programming transistor Tr_P, a reading transistor Tr_R, and a variable resistive device VR. A gate electrode of the programming transistor Tr_P may be electrically connected with the programming word line WL_P. A source electrode of the programming transistor Tr_P may be electrically connected with the programming bit line BL_P. A drain electrode of the programming transistor Tr_P may be electrically connected with a gate electrode of the reading transistor Tr_R. A source electrode of the reading transistor Tr_R may be electrically connected with the reading bit line BL_R. A drain electrode of the reading transistor Tr_R may be electrically connected with the reference voltage line VL_R. The gate electrode of the reading transistor Tr_R may be electrically connected with a lower electrode of the variable resistive device VR. An upper electrode of the variable resistive device VR may be electrically connected with the reading word line WL_R.

The synapse S may further include a load resistor R coupled between the drain electrode of the programming transistor Tr_P and the gate electrode of the reading transistor Tr_R, and between the drain electrode of the programming transistor Tr_P and the lower electrode of the variable resistive device VR. A first electrode of the load resistor R may be electrically connected with the gate electrode of the reading transistor Tr_R and the lower electrode of the variable resistive device VR, and a second electrode of the load resistor R may be electrically connected with the drain electrode of the programming transistor Tr_P. The load resistor R may have various fixed resistance values. The load resistor R can prevent or reduce overflow current in the synapse S, and can match the impedance of the synapse S. In addition, the load resistor R can prevent the programming transistor Tr_P from being turned on by applying the same voltage applied to the gate electrode of the reading transistor Tr_R to the drain electrode of the programming transistor Tr_P. Accordingly, the load resistor R may prevent current leakage.

The variable resistive device VR may include at least one of a resistive random access memory (ReRAM) element, a phase-changeable random access memory (PCRAM) element, a magneto-resistive random access memory (MRAM) element, and a conductive bridging random access memory (CBRAM) element. In the embodiment illustrated in FIG. 2, the variable resistive device VR may include a resistive random access memory (ReRAM) element.

The reading transistor Tr_R may include a C-Axis Aligned Crystal In—Ga—Zn—O Thin Film Transistor (CAAC IGZO TFT). The CAAC IGZO TFT has a lower leakage current and higher on/off current ratio than a single crystalline silicon transistor. That is, the CAAC IGZO TFT can achieve a high on/off current ratio with small variations in a gate voltage. Accordingly, the CAAC IGZO TFT can more easily secure multiple resistance levels.

Programming Operation I (Potentiating Mode)

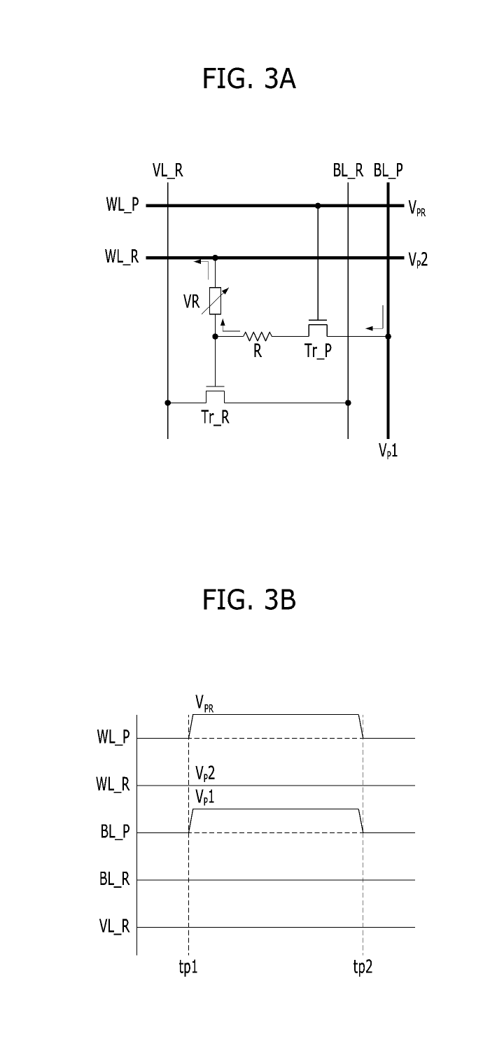

FIG. 3A is a schematic circuit diagram showing an operation of potentiating the variable resistive device VR of the synapse S of FIG. 2 in accordance with an embodiment of the present disclosure. FIG. 3B is a timing diagram showing the operation of potentiating the variable resistive device VR of FIG. 3A in accordance with an embodiment of the present disclosure.

Before the variable resistance device VR is potentiated, a resistance level of the variable resistive device VR may be at an initial resistance level, e.g., at a high resistance state (HRS). The variable resistive device VR may be potentiated during a programming time period, which may be from a start time tp1 to an end time tp2. During the programming time period, a programming voltage VpR, which turns on the programming transistor Tr_P, may be applied to the programming word line WL_P; a potentiation supply voltage Vp1, which programs the variable resistive device VR, may be applied to the programming bit line BL_P; and a potentiation discharge voltage Vp2, which drains a current used to program the variable resistive device VR, may be applied to the reading word line WL_R. The programming bit line BL_P may be fully pre-charged prior to the start time tp1. That is, after the programming bit line BL_P is fully pre-charged, the programming voltage VpR may be applied to the programming word line WL_P, so that the programming transistor Tr_P may be turned on.

The potentiation supply voltage Vp1 may be a relative high voltage, and the potentiation discharge voltage Vp2 may be a relatively low voltage. That is, the potentiation supply voltage Vp1 may be higher than the potentiation discharge voltage Vp2. In some embodiments, the potentiation discharge voltage Vp2 may be a ground voltage, e.g., 0V. For example, no voltage may be applied to the reading word line WL_P. The potentiation supply voltage Vp1 may be any positive voltage. A potentiation current, which may potentiate the variable resistive device VR, may flow along arrows shown in FIG. 3A. According to an amount, e.g., a magnitude, of the potentiation current, the resistance level of the variable resistive device VR may be decreased. That is, the synapse S may be trained or potentiated. As the variable resistive device VR is potentiated, the resistance level of the variable resistive device VR may gradually change from the high resistance state (HRS) to a low resistance state (LRS). That is, a conductance of the variable resistive device VR can be increased.

The potentiation supply voltage Vp1 may be also applied to the gate electrode of the reading transistor Tr_R, and thus, the reading transistor Tr_R can be turned on. However, at this time, at least one of the reading bit line BL_R or the reference voltage line VL_R may be floated. Accordingly, the reading transistor Tr_R may be in a substantially turned off state or a floated state. Thus, current is substantially blocked from passing through the reading transistor Tr_R. In an embodiment, the substantially same voltage may be applied to the reading bit line BL_R and the reference voltage line VL_R, so that the reading transistor Tr_R may be in a turned off state or a floated state.

Programming Operation II (Depressing Mode)

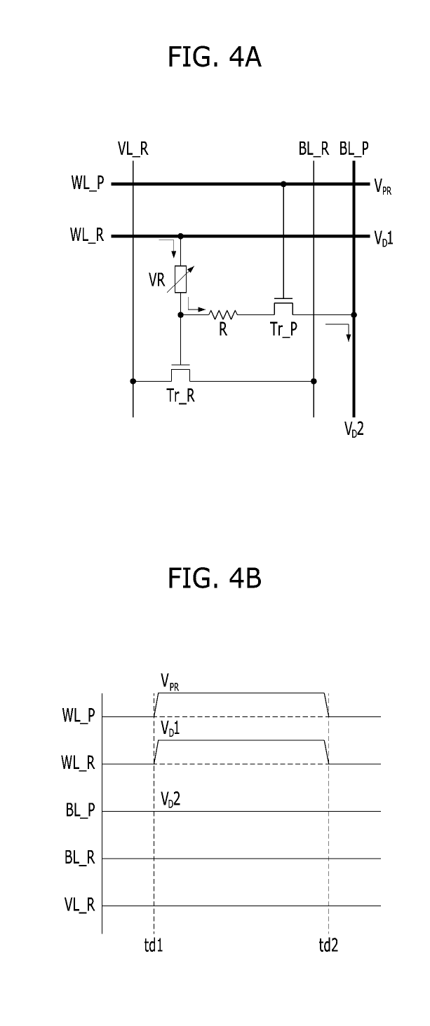

FIG. 4A is a schematic circuit diagram showing an operation of depressing the variable resistive device VR of the synapse S of FIG. 2 in accordance with an embodiment of the present disclosure. FIG. 4B is a timing diagram showing the operation of depressing the variable resistive device VR of FIG. 4A in accordance with an embodiment of the present disclosure.

Before the variable resistance device VR is depressed, a resistance level of the variable resistive device VR may be at a low resistance state (LRS). The variable resistive device VR is being depressed during a programming time period, which extends from a start time td1 to an end time td2. During the programming time period, a programming voltage VpR, which turns on the programming transistor Tr_P, may be applied to the programming word line WL_P; a depression supply voltage V_{D}1, which programs the variable resistive device VR, may be applied to the reading word line WL_R; and a depression discharge voltage V_{D}2, which drains a current used to program the variable resistive device VR, may be applied to the programming bit line BL_P. The programming bit line BL_P may be sufficiently pre-charged prior to the start time td1, such that the programming transistor Tr_P may be turned on when the programming voltage VₚR is applied to the programming word line WL_P.

The depression supply voltage V_{D}1 may be a relative high voltage, and the depression discharge voltage V_{D}2 may be a relative low voltage. That is, the depression supply voltage V_{D}1 may be higher than the depression discharge voltage V_{D}2. In some embodiments, the depression discharge voltage V_{D}2 may be a ground voltage, e.g., 0V. For example, no voltage may be applied to the reading bit line BL_P. A depression current, which depresses the variable resistive device VR, may flow along arrows shown in FIG. 4A. According to an amount, e.g., a magnitude, of the depression current, the resistance level of the variable resistive device VR may be increased. That is, the synapse S may be depressed. As the variable resistive device VR is depressed, the resistance level of the variable resistive device VR may be gradually change from the low resistance state (LRS) to the high resistance state (HRS). That is, the conductance of the variable resistive device VR may be decreased.

The depression supply voltage V_{D}1 may be also applied to the gate electrode of the reading transistor Tr_R, and thus the reading transistor Tr_R may be turned on. However, at this time, at least one of the reading bit line BL_R and the reference voltage line VL_R may be floated. Accordingly, the reading transistor Tr_R may be in a substantially turned off state or a floated state. Thus, current is substantially blocked from passing through the reading transistor Tr_R. Otherwise, the substantially same voltage may be applied to the reading bit line BL_R and to the reference voltage line VL_R, so that the reading transistor Tr_R may be in a turned off state or a floated state.

Reading Operation (Read-Out Mode)

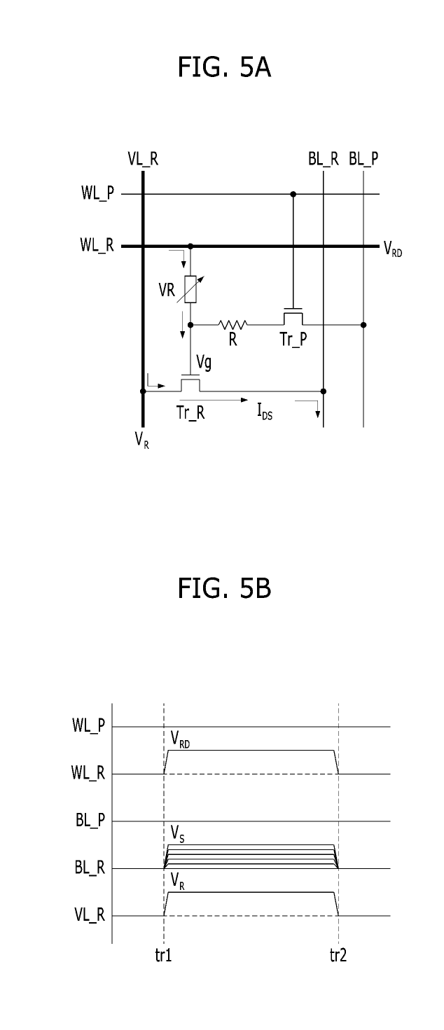

FIG. 5A is a schematic circuit diagram showing an operation of reading out data of the variable resistive device V_{R} of the synapse S of FIG. 2 in accordance with an embodiment of the present disclosure. FIG. 5B is a timing diagram showing the operation of reading out the data of the variable resistive device V_{R} of FIG. 5A in accordance with an embodiment of the present disclosure. The data may correspond to a present resistance level or conductance of the variable resistive device V_{R} of the synapse S.

During a read-out time period from a start time tr1 to an end time tr2, a read voltage V_{RD} may be applied to the reading word line WL_R, and a reference voltage V_{R} may be applied to the reference voltage line VL_R. The read voltage V_{RD} may be applied to the upper electrode of the variable resistive device V_{R}. A specific voltage, which is lower than the read voltage V_{RD}, may be applied to the gate electrode of the reading transistor Tr_R by the variable resistive device V_{R}. When the reading transistor Tr_R is turned on, a read current may flow from the reference voltage line VL_R to the reading bit line BL_R. A gate voltage Vg applied to the gate electrode of the reading transistor Tr_R may be the specific voltage, which is lower than the read voltage V_{RD} that is applied to the upper electrode of the variable resistive device V_{R}. That is, Vg=V_{RD}−V_{VR}, where Vg is the gate voltage applied to the gate electrode of the reading transistor Tr_R, V_{RD} is the read voltage on the reading word line WL_R, and V_{VR} is a variable resistive device voltage dropped across the variable resistive device V_{R}.

The gate voltage Vg may be varied depending on the resistance levels of the variable resistive device VR. For example, when the resistance level of the variable resistive device VR is the high resistance state (HRS), the variable resistive device voltage V_{VR} may be relatively high and the gate voltage Vg may be relatively low. Accordingly, a channel size of the reading transistor Tr_R may be relatively small and current or voltage driving capabilities of the reading transistor Tr_R may be relatively weak. Accordingly, a synapse voltage Vs may be relatively low, and an output current I_{DS} of the reading transistor Tr_R may be relatively small.

When the resistance level of the variable resistive device V_{R} is in the low resistance state (LRS), the variable resistive device voltage V_{VR} may be relatively low and the gate voltage Vg of the reading transistor Tr_R may be relatively high. Accordingly, the channel size of the reading transistor Tr_R may be relatively large and the current or voltage driving capabilities of the reading transistor Tr_R may be relatively strong. Accordingly, the synapse voltage Vs may be relatively high, and the output current I_{DS} of the reading transistor Tr_R may be relatively great. Various levels of the synapse voltage Vs output onto the reading bit line BL_R, which depend on the resistance state of the variable resistive device VR, are shown in FIG. 5B.

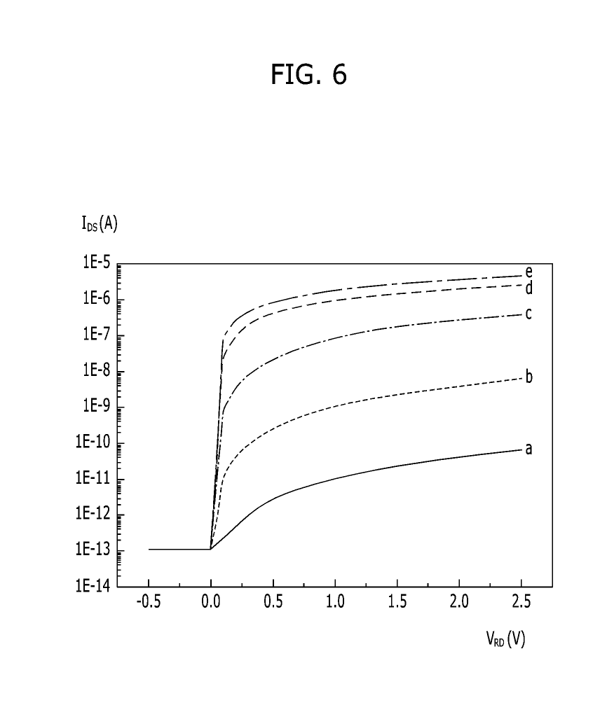

FIG. 6 is a log-scale graph illustrating a characteristic of the output current I_{DS} of the reading transistor Tr_R depending on the read voltage V_{RD} of the synapse S in accordance with an embodiment of the present disclosure. When the resistance level of the variable resistive device V_{R} is in the high resistance state (HRS), the variable resistive device voltage V_{VR} dropped across the variable resistive device V_{R} may be relatively great, so that the gate voltage Vg applied to the gate electrode of the reading transistor Tr_R may be relatively low. Accordingly, as shown by Curve ‘a,’ under a range of read voltages V_{RD}, the output current IDs of the reading transistor Tr_R may be relatively small.

When the resistance level of the variable resistive device V_{R} is in the low resistance state (LRS), the variable resistive device voltage V_{VR} dropped across the variable resistive device V_{R} may be relatively small, so that the gate voltage Vg applied to the gate electrode of the reading transistor Tr_R may be relatively high. Accordingly, as shown by Curve ‘e,’ under the range of read voltages V_{RD}, the output current IDs of the reading transistor Tr_R may be relatively great.

In FIG. 6, the curves representing relatively low currents across a range of read voltages, e.g., Curve ‘a’ and Curve ‘b,’ illustrate the output currents I_{DS} of the reading transistor Tr_R when the resistance level of the variable resistive device VR is in the high resistance state (HRS), and the curves representing relatively high currents across the range of read voltages, e.g., Curve ‘c,’ Curve ‘d,’ and Curve ‘e,’ illustrate the output currents I_{DS} of the reading transistor Tr_R when the resistance level of the variable resistive device V_{R} is in the low resistance state (LRS). In an implementation, a difference between the Curve ‘a’ and the Curve ‘e’ at the same read voltage level is in a range of about 10⁵ A to 10⁶ A. That is, the current differences associated with different resistance levels of the variable resistive device VR may be relatively great. Accordingly, the synapse S in accordance with the embodiment of the present disclosure can have a plurality of distinct resistance levels, e.g., a plurality of distinct learning states.

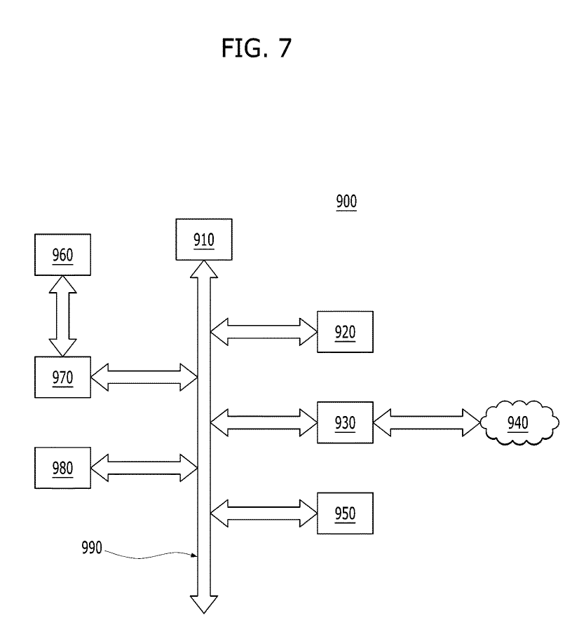

FIG. 7 is a diagram schematically illustrating a pattern recognition system 900 in accordance with an embodiment of the present disclosure. For example, the pattern recognition system 900 may include a speech recognition system, an imaging recognition system, a code recognition system, a signal recognition system, and one or more systems for recognizing various patterns.

Referring to FIG. 7, the pattern recognition system 900 in accordance with the embodiment of the present disclosure may include a Central Processing Unit (CPU) 910, a memory unit 920, a communication control unit 930, a network 940, an output unit 950, an input unit 960, an Analog-Digital Converter (ADC) 970, a neuromorphic unit 980, and a bus 990. The CPU 910 may generate and transmit various signals for a learning process of the neuromorphic unit 980, and perform various processes and functions for recognizing patterns according to an output from the neuromorphic unit 980. For example, the CPU 910 may perform processes and functions for recognizing speech and imaging patterns based on the output from the neuromorphic unit 980.

The CPU 910 may be connected with the memory unit 920, the communication control unit 930, the output unit 950, the ADC 970, and the neuromorphic unit 980 through the bus 990.

The memory unit 920 may store various pieces of information, which are required to be stored in the pattern recognition system 900. The memory unit 920 may include one or more of a volatile memory device, such as DRAM or SRAM, a nonvolatile memory, such as PRAM, MRAM, ReRAM or NAND flash memory, and various memory units, such as a Hard Disk Drive (HDD) and a Solid State Drive (SSD).

The communication control unit 930 may transmit and/or receive data to and/or from a communication control unit of another system through the network 940. For example, the communication control unit 930 may transmit speech and/or image recognition data through the network 940.

The output unit 950 may output data in various manners. For example, the output unit 950 may include one or more of a speaker, a printer, a monitor, a display panel, a beam projector, a hologrammer, and another output device. The output unit 950 may output, for example, speech and/or image recognition data.

The input unit 960 may include one or more a microphone, a camera, a scanner, a touch pad, a keyboard, a mouse, a mouse pen, and a sensor.

The ADC 970 may convert analog data inputted from the input unit 960 into digital data.

The neuromorphic unit 980 may perform learning or recognition using the data outputted from the ADC 970, and output data corresponding to recognized patterns. The neuromorphic unit 980 may include one or more of the neuromorphic devices in accordance with the various embodiments described above.

According to the present disclosure, a synapse of a neuromorphic device can include two transistors, such as a programming transistor and a reading transistor, as well as one variable resistive device electrically connected a drain electrode of the programming transistor and a gate electrode of the reading transistor. Thus, a current difference between the minimum current through the variable resistive device and the maximum current through the variable resistive device can became very large. Accordingly, a number of distinct resistance levels of the synapse can be increased.

Although various embodiments have been described for illustrative purposes, it will be apparent to those skilled in the art that various changes and modifications may be made without departing from the spirit and scope of the disclosure, as defined in the following claims.

What is claimed is:

1. A synapse of a neuromorphic device, the synapse comprising:
a variable resistive device;
a first transistor; and
a second transistor,
wherein a drain electrode of the first transistor and a gate electrode of the second transistor are electrically connected in common with a first electrode of the variable resistive device.

2. The synapse of claim 1, wherein a gate electrode of the first transistor is electrically connected with a first row line.

3. The synapse of claim 2, wherein a second electrode of the variable resistive electrode is electrically connected with a second row line.

4. The synapse of claim 3, wherein the first row line and the second row line extend in parallel with each other in a row direction.

5. The synapse of claim 1, wherein a source electrode of the first transistor is electrically connected with a first column line.

6. The synapse of claim 5, wherein a source electrode of the second transistor is electrically connected with a second column line.

7. The synapse of claim 6, wherein the first column line and the second column line extend in parallel with each other in a column direction.

8. The synapse of claim 1, wherein a drain electrode of the second transistor is electrically connected with a reference voltage line.

9. The synapse of claim 1, further comprising:
a load resistor coupled between the drain electrode of the first transistor and the first electrode of the variable resistive device.

10. The synapse of claim 9, wherein the load resistor has various fixed resistance values.

11. The synapse of claim 1, wherein the variable resistive device comprises one of a resistive random access memory (ReRAM) element, a phase-changeable random access memory (PCRAM) element, a magneto-resistive random access memory (MRAM) element, and a conductive bridging random access memory (CBRAM) element.

12. The synapse of claim 1, wherein a resistance state of the variable resistive device is decreased when a programming voltage is applied to a gate electrode of the first transistor, a first potentiation voltage is applied to a source electrode of the first transistor, and a second potentiation voltage is applied to a second electrode of the variable resistive device, the second potentiation voltage being less than the first potentiation voltage.

13. The synapse of claim 1, wherein a resistance state of the variable resistive device is increased when a programming voltage is applied to a gate electrode of the first transistor, a first depression voltage is applied to a second electrode of the variable resistive device, and a second depression voltage is applied to a source electrode of the first transistor, the second depression voltage being less than the first depression voltage.

14. The synapse of claim 1, wherein the variable resistive device has a plurality of resistance levels, and
wherein a gate voltage and a transistor current of the second transistor are changed according to the plurality of resistance levels of the variable resistive device.

15. A synapse array comprising:
a plurality of row lines extending in a row direction, the plurality of row lines including a plurality of first row lines and a plurality of second row lines;
a plurality of column lines extending in a column direction; and
a plurality of synapses disposed at intersection regions between the row lines and the column lines,
wherein each of the plurality of first row lines and each of the plurality of second row lines are electrically connected with one of the plurality of synapses, respectively,
wherein each of the plurality of synapses comprises:
a first transistor including a gate electrode electrically connected with one of the plurality of first row lines;
a variable resistive device electrically connected with one of the plurality of second row lines; and
a second transistor including a gate electrode electrically connected with one of the plurality of second row lines through the variable resistive device.

16. The synapse array of claim 15, wherein a first electrode of the variable resistive device is electrically connected with a drain electrode of the first transistor, and a second electrode of the variable resistive device is electrically connected with the corresponding one of the plurality of second row lines.

17. The synapse array of claim 15, wherein each of the plurality of column lines comprises a first column line and a second column line being electrically connected with one of the plurality of synapses, respectively.

18. The synapse array of claim 17, wherein the first column line of each of the plurality of column lines is electrically connected with a source electrode of the first transistor of each of the plurality of synapses, respectively.

19. The synapse array of claim 17, wherein the second column line of each of the plurality of column lines is electrically connected with a source electrode of the second transistor of each of the plurality of synapses, respectively.

20. The synapse array of claim 15, wherein the plurality of column lines further comprise a plurality of reference voltage lines, respectively, each of the plurality of reference voltage lines being electrically connected with a drain electrode of the second transistor of each of the plurality of synapses, respectively.
